(19) United States
(12) Patent Application Publication
(10) Pub. No.: US 2021/0124227 A1
(43) Pub. Date: Apr. 29, 2021

(54) DISPLAY PANEL, CONTROL METHOD THEREOF AND DISPLAY DEVICE

(71) Applicant: BOE TECHNOLOGY GROUP CO., LTD., Beijing (CN)

(72) Inventors: Rui LI, Beijing (CN); Haiyan SUN, Beijing (CN); Hao MIAO, Beijing (CN); Pengju ZHANG, Beijing (CN); Mingxing LIU, Beijing (CN); Hong ZHU, Beijing (CN); Yajie WANG, Beijing (CN); Jingzhe FANG, Beijing (CN)

(21) Appl. No.: 16/639,724

(22) PCT Filed: Apr. 18, 2019
(86) PCT No.: PCT/CN2019/083175

§ 371 Date: Feb. 17, 2020

(30) Foreign Application Priority Data
Apr. 28, 2018 (CN) 201810399212.X

(51) Int. Cl. G02F 1/155; G02F 1/1516; G02F 1/157; G02F 1/1503; G02F 1/163

(52) U.S. Cl. CPC G02F 1/155; G02F 1/15165; G02F 1/163; G02F 1/1503; G02F 1/157

(57) ABSTRACT

A display including a first substrate, a first electrochromic layer, a light emitting layer, a second electrochromic layer and a second substrate that are sequentially stacked are provided. A display area of the display panel includes a plurality of sub-pixels arranged in an array, the first electrochromic layer includes a plurality of first sub-electrochromic layers corresponding to the plurality of sub-pixels, and the second electrochromic layer includes a plurality of second sub-electrochromic layers corresponding to the plurality of sub-pixels, each first sub-electrochromic layer and each second sub-electrochromic layer are configured to switch between a light-transmissive state and a light-shielding state in response to an external voltage. The display panel can switch between a double-sided display state and a single-sided display state, meanwhile a phenomenon of mirror images can be avoided in case of double-sided display state.

### CROSS-REFERENCE TO RELATED APPLICATIONS

This application claims the priority benefit of the patent application No. 201810399212.X filed with the Chinese Patent Office on Apr. 28, 2018, the disclosure of which is incorporated herein by reference.

### TECHNICAL FIELD

The present disclosure relates to the field of optoelectronic technology, and in particular, embodiments of the disclosure relate to a display panel, a control method thereof, and a display device.

### BACKGROUND

With the development of display technology, people tend to need a double-sided display device capable of displaying images on both sides of the display device. The double-sided display device may be applied in business halls of communication industry, government windows, financial industry, transportation industry, and window industry, e.g. various public places with high traffic such as airports, railway stations, subway stations and canteens. Therefore, the double-sided display device has broad application prospects.

Existing OLED double-sided display panels comprise thin metal electrodes and translucent materials, but the images displayed on the front side and back side of the display panel tend to be mirror images, which affects the visual effect of double-sided displaying and the viewing effect of a user. Another way of manufacturing a double-sided display panel includes bonding two top-emitting OLED devices together to achieve a double-sided displaying effect. Though a normal double-sided display effect can be achieved by means of bonding two top-emitting OLED devices together, using top-emitting OLED devices causes a high production cost, which is not suitable for large-scale applications, and is not advantageous for subsequent maintenance of the display device by the user.

### SUMMARY

An embodiment of the disclosure provides a display panel comprising a first substrate, a first electrochromic layer, a light emitting layer, a second electrochromic layer and a second substrate sequentially stacked. A display area of the display panel comprises a plurality of sub-pixels arranged in an array, the first electrochromic layer comprises a plurality of first sub-electrochromic layers corresponding to the plurality of sub-pixels, and the second electrochromic layer comprises a plurality of second sub-electrochromic layers corresponding to the plurality of sub-pixels. Each first sub-electrochromic layer of the plurality of first sub-electrochromic layers and each second sub-electrochromic layer of the plurality of second sub-electrochromic layers are configured to switch between a light-transmissive state and a light-shielding state in response to an external voltage.

In some embodiments, each of the first sub-electrochromic layer and the second sub-electrochromic layer comprises a first electrode layer, a second electrode layer, and an electrochromic material layer between the first electrode layer and the second electrode layer.

In some embodiments, the electrochromic material layer comprises N,N,N′,N′-tetraphenyl-1,4-phenylenediamine-tetraphenylphenylenediamine polymer, a chemical formula of the N,N,N′,N′-tetraphenyl-1,4-phenylenediamine-tetraphenylphenylenediamine polymer is:

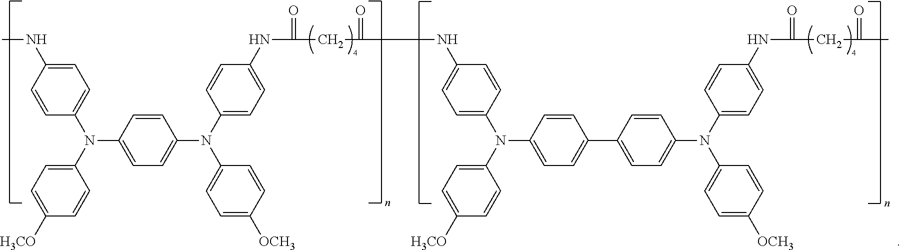

In some embodiments, each of the first electrochromic layer and the second electrochromic layer comprises a supporting electrolyte layer between the first electrode layer and the second electrode layer.

In some embodiments, the supporting electrolyte layer comprises viologen.

In some embodiments, first electrode layers of the first electrochromic layer or second electrode layers of the second electrochromic layer are connected to each other to form a continuous electrode layer.

In some embodiments, the light emitting layer comprises sub-light emitting layers corresponding to the sub-pixels of the display panel, the sub-light emitting layers comprise a red sub-light emitting layer, a green sub-light emitting layer, a blue sub-light emitting layer or a white sub-light emitting layer.

In some embodiments, each of the sub-light emitting layers comprises a cathode, an anode and an electroluminescent material layer between the cathode and the anode.

In some embodiments, the first substrate and the second substrate are made of a light-transmissive material.

In some embodiments, materials for forming the first electrode layer and the second electrode layer comprise indium tin oxide or Mg—Al alloy.

Another embodiment of the disclosure provides a display device comprising the display panel according to any one of the foregoing embodiments.

Another embodiment of the disclosure provides a method for controlling the display panel according to any one of the foregoing embodiments, each row of the plurality of sub-pixels arranged in the array comprising a plurality of first sub-pixels and a plurality of second sub-pixels located in positions different from the plurality of first sub-pixels, the method comprises: controlling the first sub-electrochromic layers and the second sub-electrochromic layers corresponding to the plurality of first sub-pixels to be in the light-transmissive state and the light-shielding state, respectively, and controlling the first sub-electrochromic layers and the second sub-electrochromic layers corresponding to the plurality of second sub-pixels to be in the light-shielding state and the light-transmissive state, respectively.

In some embodiments, two adjacent first sub-pixels in each row of sub-pixels are spaced apart by at least one second sub-pixel.

Yet another embodiment of the disclosure provides a method for controlling the display panel according to any one of foregoing embodiments, the method comprising: controlling all first sub electrochromic layers corresponding to a row of the plurality of sub-pixels arranged in the array to be in the light-transmissive state, and controlling all second sub electrochromic layers corresponding to a row of the plurality of sub-pixels arranged in the array to be in the light-shielding state.

Additional aspects and advantages of the disclosure will be further understood in the following description. In addition, those skilled in the art can appropriately combine the above-mentioned embodiments and different features in the embodiments to obtain different additional embodiments. These different additional embodiments also belong to the protection scope of the present application.

### BRIEF DESCRIPTION OF DRAWINGS

The technical solution of the above embodiments of the present disclosure will become apparent and easy to understand from the following description of the embodiments in conjunction with the drawings, in which:

FIG. 1 is a schematic partial cross-sectional view of a display panel provided by an embodiment of the disclosure;

FIG. 2 schematically shows the reaction principle of electrochromic material and supporting electrolyte material in a display panel according to an embodiment of the disclosure;

FIG. 3 shows a transmission spectrum diagram for an electrochromic material when a voltage is applied and when a voltage is not applied in a display panel according to an embodiment of the disclosure;

FIG. 4 illustrates a case where all first sub electrochromic layers in a display panel are in a light-transmissive state according to an embodiment of the present disclosure;

FIG. 5 illustrates states of the pixels on a first surface of a display panel when the display panel is in a double-sided displaying state according to an embodiment of the disclosure;

FIG. 6 illustrates states of the pixels on a second surface of a display panel that is opposite to the first surface when the display panel is in a double-sided displaying state according to an embodiment of the disclosure; and

FIG. 7 illustrates a display panel provided by an embodiment of the disclosure that is in a double-sided displaying state.

### DETAILED DESCRIPTION OF EMBODIMENTS

Hereinafter, embodiments of the present disclosure will be described in detail. Examples of the embodiments are shown in the accompanying drawings, where the same or similar reference numerals throughout represent the same or similar elements or elements having the same or similar functions. The embodiments described below with reference to the drawings are exemplary, and are only used to explain the present disclosure, and cannot be construed as limiting the scope of protection of the application.

Those skilled in the art will understand that, unless specifically stated otherwise, the words in singular form such as “a”, “an”, “the” and “this” may mean including a plurality of entities. It should be further understood that the wording “including” or “comprising” used in the specification of the disclosure means the presence of the described features, integers, steps, operations, elements and/or components, but does not exclude the presence or addition of one or more other features, integers, steps, operations, elements, components and/or combinations thereof.

It will be understood by one of ordinary skill in the art, unless otherwise defined, all terms (including technical and scientific terms) used herein have the same meaning as commonly understood by one of ordinary skill in the art to which this disclosure belongs. It should also be understood that terms such as those defined in the general dictionary should be understood to have meanings consistent with the meanings in the context of this disclosure, and unless specifically defined herein, will not be explained in an idealized or an overly formal way.

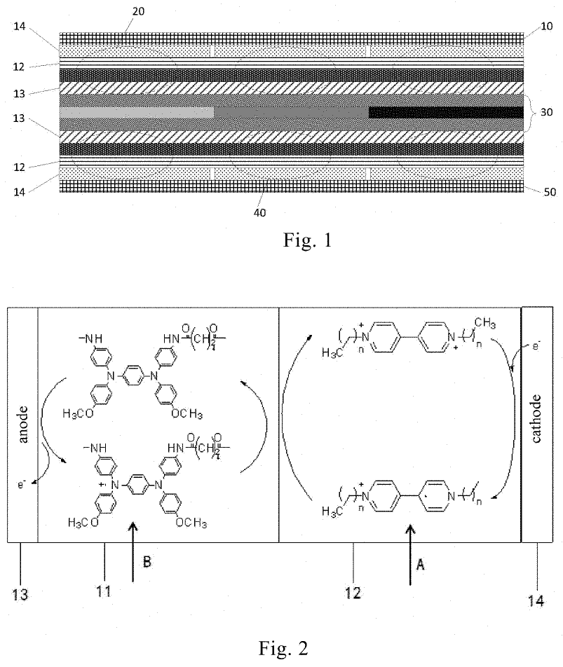

An embodiment of the disclosure provides a display panel, whose partial cross-sectional view is illustrated in FIG. 1. As shown in FIG. 1, the display panel includes a first substrate 10, a first electrochromic layer, a light emitting layer 30, a second electrochromic layer 40, and a second substrate 50 which are sequentially stacked. A display area of the display panel includes a plurality of sub-pixels arranged in an array, the first electrochromic layer includes a plurality of first sub-electrochromic layers corresponding to the plurality of sub-pixels, and the second electrochromic layer includes a plurality of second sub-electrochromic layers 40 corresponding to the plurality of sub-pixels, each first sub-electrochromic layer 20 and each second sub-electrochromic layer 40 are configured to switch between a light-transmissive state and a light-shielding state in response to an external voltage. In FIG. 1, three sub-pixels are schematically shown, accordingly, three first sub-electrochromic layers 20 and three second sub-electrochromic layers 40 are illustrated (as indicated with dashed ellipses in FIG. 1).

According to an embodiment of the disclosure, each first sub-electrochromic layer 20 and each second sub-electrochromic layer 40 in the display panel are configured to switch between the light-transmissive state and the light-shielding state (for example, a state in which a certain color is displayed) in response to receiving an external voltage, thereby blocking or transmitting light from the light-emitting layer. In an example, when the first electrochromic layer and the second electrochromic layer are in a light-shielding state under the action of an external voltage, the magnitude of the external voltage may be regulated based on the material of the electrochromic layer and an application scene of the display panel to achieve a desired display effect. The electrochromic layer mainly includes an electrochromic material. The electrochromic material undergoes a chemical reaction under the effect of an externally applied voltage, causing the color displayed by the electrochromic material to change, so that light incident onto the electrochromic layer may pass through the electrochromic layer or not pass through the electrochromic layer. In some embodiments, the electrochromic material is light-transmissive when no voltage is applied. At this time, light from the light-emitting layer can pass through the first sub-electrochromic layer 20 or the second sub-electrochromic layer 40. Therefore, the first sub-electrochromic layer 20 can control the light incident onto it to switch between a blocked state and a transmitted state, and the second sub-electrochromic layer 40 can control the light incident onto it to switch between a blocked state and a transmitted state, thus, when the light emitted from the light-emitting layer 30 passes through the first electrochromic layer and/or the second electrochromic layer, an image can be displayed, and when light emitted from the light-emitting layer 30 cannot pass through the first electrochromic layer and/or the second electrochromic layer, no image is displayed.

In an embodiment of the disclosure, the first substrate 10 and the second substrate 50 are made of a transparent glass material or a transparent plastic material. In another embodiment, a polymer material such as PMMA may also be used to form the substrate. According to an embodiment of the disclosure, each of the first sub-electrochromic layer 20 and the second sub-electrochromic layer 40 includes a first electrode layer 13, a second electrode layer 14, and an electrochromic material layer between the first electrode layer 13 and the second electrode layer 14.

The first sub-electrochromic layer 20 is configured to control light that is emitted from the light-emitting layer and incident on the first sub-electrochromic layer 20 to be blocked from passing through the first sub-electrochromic layer 20, or to transmit through the first sub-electrochromic layer 20 and exit from the first substrate 10. The second sub-electrochromic layer 40 is configured to control the light that is emitted from the light-emitting layer and incident on the second sub-electrochromic layer 40 to be blocked from passing through the second sub-electrochromic layer 40, or to transmit through the second sub-electrochromic layer 40 and exit from the second substrate 50.

The light-emitting layer 30 includes a light-emitting device as a light source. The light-emitting device generates light and emits the light towards both sides, and then the light is incident onto the first sub-electrochromic layer 20 and the second sub-electrochromic layer 40, respectively. The first sub-electrochromic layer 20 and the second sub-electrochromic layer 40 determine whether light can pass through themselves according to a state (i.e., light-transmissive state or light-shielding state) of the first sub-electrochromic layer 20 and the second sub-electrochromic layer 40. The first sub-electrochromic layer 20 may allow light emitted from the light-emitting layer 30 and incident onto the first sub-electrochromic layer 20 to be transmitted or be blocked, and the second sub-electrochromic layer 40 may allow light emitted from the light-emitting layer 30 and incident onto the second sub-electrochromic layer 40 to be transmitted or be blocked. Thus, the first substrate 10 may present a state of displaying image or not displaying image depending upon whether the light from the light emitting layer 30 passes through the first electrochromic layer or not. The second substrate 50 may present a state of displaying image or not displaying image depending on whether the light from the light emitting layer 30 passes through the second electrochromic layer or not. When the first sub-electrochromic layer 20 is in a light-shielding state, the light emitted from the light-emitting layer 30 cannot pass through the first sub-electrochromic layer 20. When the first sub-electrochromic layer 20 is in a light-transmissive state, the light emitted from the light emitting layer 30 can pass through the first sub-electrochromic layer 20 and exit from the first substrate 10. When the second sub-electrochromic layer 40 is in a light-shielding state, the light emitted from the light-emitting layer 30 cannot pass through the second sub-electrochromic layer 40. When the second sub-electrochromic layer 40 is in a light-transmissive state, the light emitted from the light emitting layer 30 can pass through the second sub-electrochromic layer 40 and exit from the second substrate 50.

FIG. 1 only illustrates a cross-sectional view of a single pixel region of a display panel, and the single pixel region can be considered as a display unit. For a display panel comprising a plurality of display units, all first sub-electrochromic layer 20 of the plurality of display units are located on one side of the display device, and all second sub-electrochromic layer 40 of the plurality of display units are located on another side of the display device opposite to the one side. When the display panel is operating, first sub-electrochromic layers and second sub-electrochromic layers of some of the plurality of display units can be controlled to be in a light-transmissive state and a light-shielding state, respectively, while first sub-electrochromic layers and second sub-electrochromic layers of the other display units of the plurality of display units are controlled to be in a light-shielding state and a light-transmissive state, respectively, thereby realizing double-sided display of the display panel. The light-shielding state means that the light emitted from the light-emitting layer 30 cannot pass through the first sub-electrochromic layer 20 or the second sub-electrochromic layer 40, and the light-transmissive state means the light emitted from the light-emitting layer 30 can pass through the first sub-electrochromic layer 20 or the second sub-electrochromic layer 40.

The second substrate 50 presents a state of displaying images or not displaying images depending on whether the second sub-electrochromic layer is in a light-shielding state or a light-transmissive state, that is, when the second sub-electrochromic layer is in a light-shielding state, the light that is emitted from the light-emitting layer 30 and incident onto the second sub-electrochromic layer 40 is blocked from passing through the second sub-electrochromic layer 40, and when the second sub-electrochromic layer 40 is in a light-transmissive state, the light that is emitted from the light emitting layer 30 and incident onto the second sub-electrochromic layer 40 can pass through the second sub-electrochromic layer 40 and exit from the second substrate 50. In some embodiments of the disclosure, the first substrate 10 and the second substrate 50 are TFT substrates, that is, the first substrate and the second substrate both include a TFT array for controlling the light emitting layer.

According to an embodiment of the disclosure, each of the first sub-electrochromic layer 20 and the second sub-electrochromic layer 40 includes an electrochromic material layer, a first electrode 13 and a second electrode 14 located on both sides of the electrochromic material layer, respectively.

Further, according to another embodiment of the disclosure, each of the first electrochromic layer and the second electrochromic layer includes a supporting electrolyte layer between the first electrode layer and the second electrode layer. FIG. 1 illustrates two supporting electrolyte layers 12, one supporting electrolyte layer 12 is on a side of the electrochromic material layer of the first sub-electrochromic layer 20 facing away the light-emitting layer 30, and the other one is on a side of the electrochromic material layer of the second sub-electrochromic layer 40 facing away the light-emitting layer 30. The supporting electrolyte layers 12 also undergo color change under the action of an external voltage, so as to increase the contrast of the first sub-electrochromic layer 20 and the second sub-electrochromic layer 40.

As shown in FIG. 1, a first electrode layer 13 is respectively provided on sides of the electrochromic material layers of the first sub-electrochromic layer 20 and the second sub-electrochromic layer 40 facing the light-emitting layer 30. A second electrode layers 14 is respectively provided on sides of the two supporting electrolyte layers 12 facing away the light-emitting layer 30. The first electrode layer 13 and the second electrode layer 14 are configured to apply a voltage to the electrochromic material layer of the first sub-electrochromic layer 20 or the second sub-electrochromic layer 40, so as to enable the first sub-electrochromic layer, the second sub-electrochromic layer, and the supporting electrolyte layers 12 to be in a non-transparent state under the action of voltage applied, which in turn would not allow the light emitted from the light emitting layer 30 to exit from the first sub-electrochromic layer 20 or the second sub-electrochromic layer 40.

According to some embodiments of the disclosure, the supporting electrolyte layer material includes viologen, and the electrochromic material layer includes N,N,N′,N′-tetraphenyl-1,4-phenylenediamine-tetraphenyl-phenylenediamine polymer material, N,N,N′,N′-tetraphenyl-1, which is also named N,N,N′,N′-tetraphenyl-p-phenylenediamine and called TPPA for short, 4-phenylenediamine may have a CAS number of 14118-16-2. In the following description, the material of the N,N,N′,N′-tetraphenyl-p-phenylenediamine is indicated as TPPA for simplicity. The tetraphenyl-phenylenediamine material in the electrochromic materials is called TPB for short, and in the following description, it is represented as TPB. Specifically, the chemical structural formula of N,N,N′,N′-tetraphenyl-1,4-phenylenediamine-tetraphenyl-phenylenediamine material polymer may be indicated as follows:

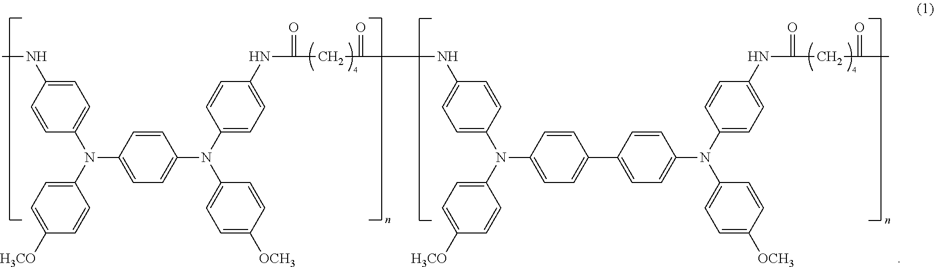

As shown in FIG. 2, if a voltage (for example, 1.5 V) is applied to the first electrode layer 13 and the second electrode layer 14, the first electrode layer 13, the second electrode layer 14, the electrochromic material layer and the supporting electrolyte layer between the first electrode layer 13 and the second electrode layer 14 form an electrolytic cell. The second electrode layer 14 serves as a cathode for a reduction reaction to generate electrons, and the first electrode layer 13 serves as an anode for an oxidation reaction to absorb electrons in the electrolytic cell. Ionization occurs in the electrolytic cell, i.e., a reduction reaction occurs to the viologen, and the viologen is decomposed into particles indicated with “A” in FIG. 2 and BF₄⁻, and the particles indicated with “A” presents blue. When no voltage is applied to the first electrode layer and the second electrode layer, the BF₄⁻ particles of the viologen are are free in the supporting electrolyte layer, and the BF₄⁻ particles and the particles indicated with A are combined to form the viologen in a transparent state. The chemical formula of viologen may be represented as the following formula (2):

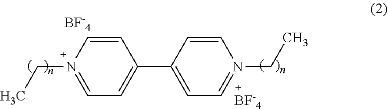

Further, when a voltage is applied to the first electrode layer and the second electrode layer, TPPA-TPB undergoes oxidation reaction under the effect of the applied voltage, forming oxidized TPPA and TPB particles indicated with “B” in FIG. 2, where TPB loses electrons to be oxidized and becomes red, and TPPA loses electrons to be oxidized and becomes green. In particular, the nitrogen atom of the material indicated by “B” in FIG. 2 is oxidized. Therefore, the red oxidized TPB particles, the green oxidized TPPA particles, and the reduced viologen particles without BF₄⁻ particles together make the first sub-electrochromic layer 20 or the second sub-electrochromic layer 40 present black, so that light that is emitted from the light emitting layer 30 and incident onto the first sub-electrochromic layer 20 or the second sub-electrochromic layer 40 will not exit from the first sub-electrochromic layer 20 or the second sub-electrochromic layer 40.

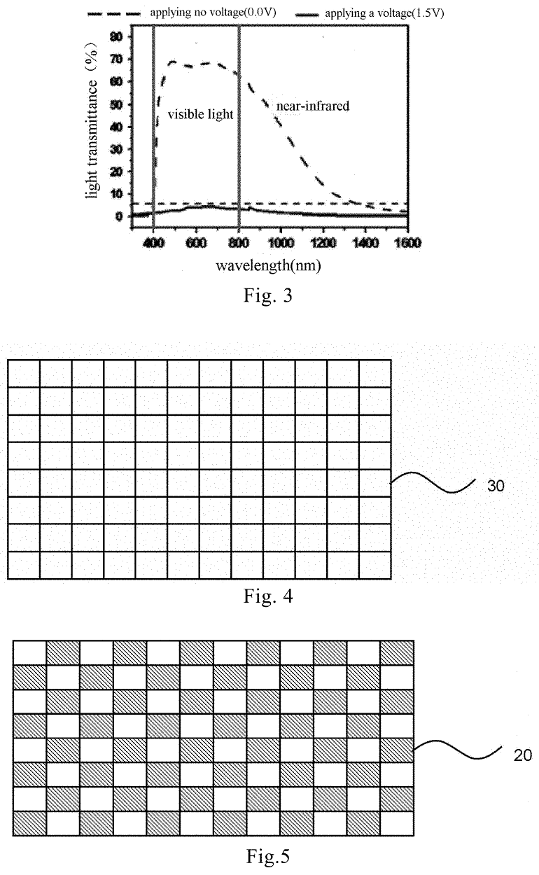

Visible light has a wavelength range of 400˜800 nm. As shown in FIG. 3, a visible light region is a region where the light wavelength is in the range of 400 nm˜800 nm, and a near-infrared region is a region where the light wavelength is greater than 800 nm. The curved dotted line in FIG. 3 represents the light transmittance of the first electrochromic layer and the second electrochromic layer when no voltage is applied to the first electrode layer and the second electrode layer, and the curved solid line indicates the light transmittance of the first electrochromic layer and the second electrochromic layer when a voltage is applied to the first electrode layer and the second electrode layer. The straight dashed line indicates the light transmittance that does not affect the image quality or cause picture crosstalk. From the foregoing description and FIG. 3, it can be appreciated that when no voltage is applied to the first electrode layer and the second electrode layer, the first electrochromic layer and the second electrochromic layer have a relatively higher transmittance in the visible light region (a region between two straight lines corresponding to 400 nm and 800 nm respectively in the coordinate chart shown in FIG. 3), which is about 70%. When a voltage is applied to the first electrode layer and the second electrode layer, the first electrochromic layer and the second electrochromic layer have a relatively lower transmittance (which is about less than 5%) in the visible light region. In an embodiment, the electrochromic material layer in the first electrochromic layer and the second electrochromic layer has a thickness of 1 um, which would meet displaying requirements without causing picture crosstalk or affecting image quality. When no voltage is applied to the first electrode layer and the second electrode layer, the electrolytic cell comprises electrons that are not absorbed by the anode. Therefore, the oxidized TPPA and TPB are converted into transparent TPPA and TPB through reduction reaction, whereas the particles indicated with A in FIG. 2 and the BF₄⁻ particles undergo oxidation reaction to obtain transparent viologen. At that time, light emitted from the light emitting layer 30 can exit from the first electrochromic layer 20 or the second electrochromic layer 40. The viologen may make it possible to utilize a lower voltage for driving the electrochromic material, thereby avoiding excessive voltage from damaging the structure of the electrochromic material.

In an embodiment of the disclosure, the voltage applied to the first electrode layer and the second electrode layer is 1.5V, but voltages of other amplitudes may be possible as actual needs, which would not limit the embodiments of the disclosure. In some embodiments, the electrochromic material and the supporting electrolyte are formed in two layers to avoid the problem of non-uniform color of the displayed images as a result of mixing of the electrochromic material and the supporting electrolyte. In some embodiments, the first electrode layers or the second electrode layers in the first electrochromic layer and the second electrochromic layer are connected to each other to form a continuous electrode layer. As shown in FIG. 1, the first electrode layers 13 in the first electrochromic layer or the second electrochromic layer are connected to each other to form a continuous electrode layer, whereas the second electrode layers 14 are spaced apart from each other. The second electrode layers 14 may be separated from each other by an insulating material. Thus, independent control of each sub-electrochromic layer can be achieved.

According to an embodiment of the disclosure, the light emitting layer includes sub-light emitting layers corresponding to sub pixels of the display panel, and the sub-light emitting layers include a red sub-light emitting layer, a green sub-light emitting layer, a blue sub-light emitting layer, or a white sub-light emitting layer. Further, in an embodiment of the disclosure, each sub-light emitting layer includes a cathode, an anode, and an electroluminescent material layer between the cathode and the anode. The electroluminescent material layer may include an electron injection layer/electron transport layer, a single primary color light emitting layer (one or more of red, green, and blue), a hole transport layer/hole injection layer (not shown in the figures), etc. which are sequentially stacked. In an embodiment of the disclosure, the first electrode layer and the second electrode layer of the first electrochromic layer and the second electrochromic layer are not shared with the cathode and the anode in the light emitting layer, so that the light emitting layer can be controlled separately. That is, the cathode and anode of the light emitting layer are only used to achieve light emission of the light emitting layer and are located in the light emitting layer 30. Further, the cathode material in the sub-light emitting layer may comprise transparent and translucent electrodes such as Mg—Ag alloy, the electron transport layer includes organic compounds and derivatives with higher excited state energy levels, the material of the single primary color light-emitting layer may comprise organic small molecular or polymer materials, and materials for the hole transport layer comprise organic compounds and derivatives with higher hole mobility and lower free potential, such as aromatic amines, carbazoles, etc. Material for the anode includes ITO transparent electrodes. ITO is a kind of n-type semiconductor material, with high conductivity, high visible light transmittance, high mechanical hardness and good chemical stability. N-type semiconductor material has a high Fermi energy level, and can form an energy band bending in solution to accumulate holes, thus is suitable to act as anode.

Further, in an embodiment of the disclosure, the first electrode layer and the second electrode layer of the first electrochromic layer and the second electrochromic layer may comprise same transparent material. According to an embodiment of the disclosure, during the operation of the display panel, when the sub-light emitting layer 30 receives a signal, the cathode electrons of the sub-light emitting layer 30 enter the single primary color light-emitting layer through the electron injection layer/electron transport layer, and the anode holes enter the single primary color light-emitting layer through the hole transport layer/hole injection layer, and the electrons and holes recombine to generate excitons. The excitons generate migration under the action of the electric field and transfer energy to the light-emitting molecules, and excite the electrons from the ground state to the excited state. The excited state energy is inactivated by a transition, which generates photons to release light energy, causing the sub light-emitting layer to emit light. For a single display unit, when the first sub-electrochromic layer 20 is in a light-transmissive state, the second sub-electrochromic layer 40 is in a light-shielding state, that is, when no voltage is applied between the first electrode layer 13 and the second electrode layer 14 of the first sub-electrochromic layer 20, a voltage is applied between the first electrode layer 13 and the second electrode layer 14 of the second sub-electrochromic layer 40, so that one side of the display unit is light-transmissive, while the other side of the display unit cannot transmit light. For a display panel including a plurality of display units, one display unit can only emit light towards one of two opposite sides of the display panel. For a plurality of display units arranged in a matrix of the display panel, some of the display units may be controlled to emit light towards one of the two opposite sides of the display panel, and the remaining display units may be controlled to emit light towards the other of the two opposite sides of the display panel. That is, a voltage is applied between the first electrode layer 13 and the second electrode layer 14 of the second sub-electrochromic layer 40 of a part of the display units, while the first electrode layer 13 and the second electrode layer 14 of the first sub-electrochromic layer 20 of the part of the display units are not supplied with a voltage, such that the first sub-electrochromic layer 20 is in a light-transmissive state, and the second sub-electrochromic layer 40 is in a light-shielding state. The first electrode layer 13 and the second electrode layer 14 of the first sub-electrochromic layer 20 of the remaining display units are supplied with a voltage, while the first electrode layer 13 and the second electrode layer 14 of the second sub-electrochromic layer 40 of the remaining display units are not supplied with a voltage, such that the first sub-electrochromic layer 20 is in a light-shielding state, and the second sub-electrochromic layer 40 is in a light-transmissive state. In this way, light emitted from the light-emitting layer 30 of a display unit can only exit from one side of the display panel, and light emitted from the light-emitting layer 30 of the remaining display units can only exit from the other side of the display panel, thereby achieving a double-sided display pattern.

In some embodiments of the disclosure, a material forming the first electrode layer and the second electrode layer may include an indium tin oxide or a magnesium aluminum alloy. For example, the first electrode layer 13 is a transparent electrode mainly made of ITO, and the second electrode layer 14 is mainly made of a transparent conductive material, e.g., a transparent alloy material, such as Mg—Ag alloy.

When the first sub-electrochromic layer 20 and the second sub-electrochromic layer 40 are in the light-transmissive state, in order to minimize energy lost by light passing through the first sub-electrochromic layer 20 and the second sub-electrochromic layer 40 and reduce the change in light color due to the loss of energy, the first electrode layer 13 and the second electrode layer 14 are mainly made of a transparent conductive material, thereby avoiding light emitted from the light emitting layer 30 from being blocked by the first electrode layer 13 and the second electrode layer 14, meanwhile avoiding significantly reducing the light flux of light that is emitted from the light emitting layer 30 and passes through the first substrate 20 and the second substrate 50.

As mentioned above, according to an embodiment of the disclosure, the light-emitting layers include sub-light emitting layers corresponding to sub pixel regions of the display panel, and the sub light emitting layers include a red sub-light emitting layer, a green sub-light emitting layer, and a blue sub-light emitting layer or a white sub-light emitting layer. In the embodiment of FIG. 1, the light-emitting layer 30 is corresponding to a single pixel unit. The light-emitting layer 30 may include at least one sub-light emitting layer. Accordingly, it can be considered that a single pixel unit includes at least one sub-pixel unit. The sub-pixel units include but are not limited to a red sub-pixel unit R, a green sub-pixel unit G, a blue pixel sub-unit B or a white pixel unit W. Accordingly, the light emitting layer 30 in a single pixel unit may include, but is not limited to one of a red sub-light emitting layer, a green sub-light emitting layer, a blue sub-light emitting layer, and a white sub-light emitting layer, or a combination thereof. In the single pixel unit shown in FIG. 1, the light-emitting layer 30 comprises a red sub-light-emitting layer, a green sub-light-emitting layer, and a blue sub-light-emitting layer which are sequentially arranged. Each sub-light-emitting layer may include a cathode, an anode, and a layer of electroluminescent material between the cathode and the anode.

Another embodiment of the disclosure provides a display device including the display panel according to any one of the foregoing embodiments. With the display panel provided in the embodiment, the display device can display images on one side, and can also display images on both sides. In some embodiments, the display device is an OLED display, that is, the light emitting layer described in the above embodiments actually constitutes an OLED device. The structure or material of the light-emitting layer can be modified or replaced by those skilled in the art to obtain other types of electroluminescent display devices.

Another embodiment of the disclosure provides a method for controlling the display panel according to any one of the foregoing embodiments. In an embodiment, each row of sub-pixels in the plurality of sub-pixels arranged in an array of the display panel includes a plurality of first sub-pixels and a plurality of second sub-pixels located in positions different from the plurality of first sub-pixels. The method may include the following steps: controlling the first sub-electrochromic layer and the second sub-electrochromic layer corresponding to the plurality of first sub-pixels to be in a light-transmissive state and a light-shielding state, respectively; and controlling the first sub-electrochromic layer and the second sub-electrochromic layer corresponding to the plurality of second sub-pixels to be in a light-shielding state and a light-transmissive state, respectively. The first sub-pixel and the second sub-pixel are in different positions in each row of the sub-pixels. All first sub-pixels in the light-transmissive state can present an image on a first surface of the display panel, and all second sub-pixels in the light-transmissive state can present images on another surface of the display panel that is opposite to the first surface, thereby realizing the double-sided display function of the display panel.

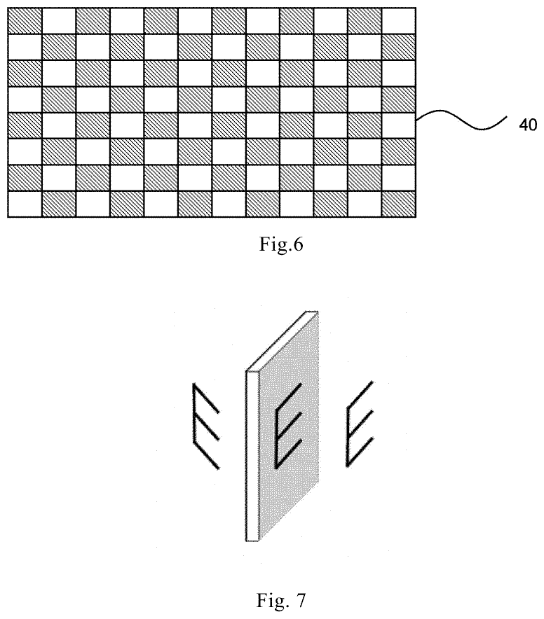

Next, the method for enabling a display panel to achieve double-sided displaying will be explained by way of specific examples. As mentioned above, each row of sub-pixels in the plurality of sub-pixels arranged in an array of the display panel includes a plurality of first sub-pixels and a plurality of second sub-pixels located in positions different from the plurality of first sub-pixels. The first sub-pixel and the second sub-pixel mentioned herein are for distinguishing sub-pixels at different positions in the same row in the sub-pixel array. In practice, which sub-pixels are the first sub-pixel and which sub-pixels are the second sub-pixel depend on the image to be displayed. In an embodiment, a same voltage signal may be applied to first sub-electroluminescent layers corresponding to the first sub-pixels, so that the first sub-pixels have substantially the same light transmittance. As shown in FIG. 5 to FIG. 6, the white portion indicates that first sub-electrochromic layers 20 and second sub-electrochromic layers 40 are in the light-transmissive state, and the shaded portion indicates that first sub-electrochromic layers 20 and second sub-electrochromic layers 40 are in the light-shielding state. The white region in FIG. 5 and FIG. 6 can be regarded as the first sub-pixels, and the shaded region can be regarded as the second sub-pixels. It can be understood that if FIG. 5 shows the display state of the first sub-pixels and the second sub-pixels on a first surface of the display panel, then FIG. 6 shows the display state of the first sub-pixels and the second sub-pixels on a second surface of the display panel opposite to the first surface.

According to an embodiment of the disclosure, two adjacent first sub-pixels in each row of sub-pixels are spaced apart by at least one second sub-pixel. Although FIG. 5 and FIG. 6 show that a single first sub-pixel and a single second sub-pixel are alternately arranged, that is, two adjacent first sub-pixels in each row of sub-pixels are separated by one second sub-pixel, the protection scope of the application is not so limited. There may be two or more second sub-pixels between two adjacent first sub-pixels in each row of sub-pixels, which may be determined according to the actual image to be displayed, e.g., a desired image resolution or the like.

For a display panel having double-sided display function, the sub-light emitting layer in each sub-pixel of the display panel actually emits light towards two opposite surfaces of the display panel at the same time, but the light emitted by each sub-light emitting layer is allowed to pass through only one surface of the display panel, but not another surface opposite to the one surface. Therefore, for a single sub-pixel of the display panel in a double-sided displaying state mentioned in the embodiments of the disclosure, it actually has two surfaces facing each other that are in a displaying state and a non-displaying state, respectively.

It can be understood that, for the display panel provided by the embodiments of the disclosure, all the first sub-electrochromic layers are on one side of the display panel, and all the second sub-electrochromic layers are on another side of the display panel opposite to the one side. During the operation of the display panel, the first sub-electrochromic layers 20 of the first sub-pixels are controlled to be in a light-shielding state, that is, a voltage is applied to the first sub-electrochromic layer. The second sub-electrochromic layers 40 of the second sub-pixels are controlled to be in a light-shielding state, that is, a voltage is applied to the second sub-electrochromic layer. In addition, the second sub-electrochromic layers 40 of the first sub-pixels are controlled to be in a light-transmitting state, e.g., the second sub-electrochromic layers 40 of the first sub-pixel layers are not supplied with a voltage, and the first sub-electrochromic layers 40 of the second sub-pixels are controlled to be in a light-shielding state, e.g., no voltage is applied to the first sub-electrochromic layers 40 of the second sub-pixel layers. With this method, it is achieved that one side of a sub-pixel (e.g., first sub-pixel) can transmit light emitted from the sub-light emitting layer 30, and the other side cannot transmit light emitted from the sub-light emitting layer 30. The case for the second sub-pixel is contrary to the first sub-pixel, thereby achieving a normal double-sided displaying by the display device, as shown in FIG. 7, no mirroring phenomenon occurs.

Yet another embodiment of the disclosure provides another method for controlling the display panel of any of the foregoing embodiments, which includes: controlling all first sub-electrochromic layers corresponding to a row of sub-pixels of a plurality of sub-pixels arranged in an array of the display panel to be in a light-transmissive state, and controlling all second sub-electrochromic layers corresponding to a row of sub-pixels in the plurality of sub-pixels arranged in an array to be in a light-shielding state. For example, instead of applying a voltage to all the first sub-electrochromic layers in each row of sub-pixels, all second sub-electrochromic layers in each row of sub-pixels are supplied with a voltage, so that all the first sub-electrochromic layers in each row of sub-pixels are in a light-transmissive state, and all the second sub-electrochromic layers in each row of sub-pixels are in a light-shielding state, thereby realizing a single-sided image display. For example, FIG. 4 illustrates a case where each of the first sub-electrochromic layers of the display panel is in a light-transmissive state.

In summary, an embodiment of the disclosure provides a display panel including a first substrate, a first electrochromic layer, a light-emitting layer, a second electrochromic layer, and a second substrate that are sequentially stacked. The display area of the display panel includes a plurality of sub-pixels arranged in an array, the first electrochromic layer includes a plurality of first sub-electrochromic layers corresponding to the plurality of sub-pixels, and the second electrochromic layer comprises a plurality of second sub-electrochromic layers corresponding to the plurality of sub-pixels, each first sub-electrochromic layer and each second sub-electrochromic layer are configured to switch between a light-transmissive state and a light-shielding state in response to an external voltage. In some embodiments, the first electrochromic layer and the second electrochromic layer include an electrochromic material. When a voltage is applied to the first electrochromic layer or the second electrochromic layer, the color of the electrochromic material changes, so that light emitted by the light-emitting layer is blocked by the electrochromic material, that is, the light transmittance of the first electrochromic layer or the second electrochromic layer is greatly reduced, so that visible light transmittance for the first electrochromic layer or the second electrochromic layer is less than e.g. 5%. When no voltage is supplied to the first electrochromic layer or the second electrochromic layer, the first electrochromic layer and the second electrochromic layer are in a light-transmitting state, so that light emitted from the light-emitting layer is transmitted from the first electrochromic layer to the first substrate and exits from the first substrate, or the light from the light-emitting layer is transmitted from the second electrochromic layer to the second substrate and exits from the second substrate. By controlling each of the sub-electrochromic layers of the first electrochromic layer and the second electrochromic layer in a similar manner, the effects of double-sided display and single-sided display can be achieved.

It should be understood that the first substrate 10, the first electrochromic layer, the first sub-electrochromic layer 20, the second electrochromic layer, the second sub-electrochromic layer 40, and the second substrate 50 mentioned in the embodiments of the disclosure are only for facilitating explanation and analysis of the present disclosure, rather than limiting the names of structure layers of the display panel in practice.

What is stated above is only part of the embodiments of the present disclosure. It should be noted that for those of ordinary skill in the art, several modifications and improvements can be made without departing from the principles of the present disclosure. These improvements and modifications should be regarded as falling within the protection scope of the application.

1. A display panel comprising a first substrate, a first electrochromic layer, a light emitting layer, a second electrochromic layer and a second substrate sequentially stacked,
wherein a display area of the display panel comprises a plurality of sub-pixels arranged in an array, the first electrochromic layer comprises a plurality of first sub-electrochromic layers corresponding to the plurality of sub-pixels, and the second electrochromic layer comprises a plurality of second sub-electrochromic layers corresponding to the plurality of sub-pixels,
wherein each first sub-electrochromic layer of the plurality of first sub-electrochromic layers and each second sub-electrochromic layer of the plurality of second sub-electrochromic layers are configured to switch between a light-transmissive state and a light-shielding state in response to an external voltage.

2. The display panel according to claim 1, wherein each of the first sub-electrochromic layer and the second sub-electrochromic layer comprises a first electrode layer, a second electrode layer, and an electrochromic material layer between the first electrode layer and the second electrode layer.

3. The display panel according to claim 2, wherein the electrochromic material layer comprises N,N,N′,N′-tetraphenyl-1,4-phenylenediamine-tetraphenylphenylenediamine polymer, a chemical formula of the N,N,N′,N′-tetraphenyl-1,4-phenylenediamine-tetraphenylphenylenediamine polymer is:

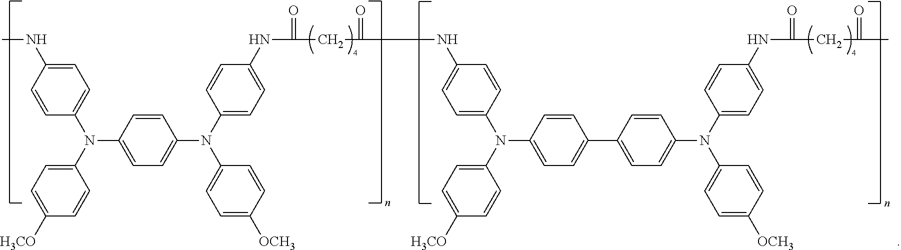

4. The display panel according to claim 2, wherein each of the first electrochromic layer and the second electrochromic layer comprises a supporting electrolyte layer between the first electrode layer and the second electrode layer.

5. The display panel according to claim 4, wherein the supporting electrolyte layer comprises viologen.

6. The display panel according to claim 2, wherein first electrode layers of the first electrochromic layer or second electrode layers of the second electrochromic layer are connected to each other to form a continuous electrode layer.

7. The display panel according to claim 2, wherein the light emitting layer comprises sub-light emitting layers corresponding to the sub-pixels of the display panel, the sub-light emitting layers comprise a red sub-light emitting layer, a green sub-light emitting layer, a blue sub-light emitting layer or a white sub-light emitting layer.

8. The display panel according to claim 7, wherein each of the sub-light emitting layers comprises a cathode, an anode and an electroluminescent material layer between the cathode and the anode.

9. The display panel according to claim 1, wherein the first substrate and the second substrate are made of a light-transmissive material.

10. The display panel according to claim 2, wherein materials for forming the first electrode layer and the second electrode layer comprise indium tin oxide or Mg—Al alloy.

11. A display device comprising the display panel according to claim 1.

12. A method for controlling the display panel according to claim 1, each row of the plurality of sub-pixels arranged in the array comprising a plurality of first sub-pixels and a plurality of second sub-pixels located in positions different from the plurality of first sub-pixels, wherein the method comprises:
controlling the first sub-electrochromic layers and the second sub-electrochromic layers corresponding to the plurality of first sub-pixels to be in the light-transmissive state and the light-shielding state, respectively, and
controlling the first sub-electrochromic layers and the second sub-electrochromic layers corresponding to the plurality of second sub-pixels to be in the light-shielding state and the light-transmissive state, respectively.

13. The method according to claim 12, wherein two adjacent first sub-pixels in each row of sub-pixels are spaced apart by at least one second sub-pixel.

14. A method for controlling the display panel according to claim 1, comprising:
controlling all first sub electrochromic layers corresponding to a row of the plurality of sub-pixels arranged in the array to be in the light-transmissive state, and
controlling all second sub electrochromic layers corresponding to a row of the plurality of sub-pixels arranged in the array to be in the light-shielding state.

15. The display device according to claim 11, wherein each of the first sub-electrochromic layer and the second sub-electrochromic layer comprises a first electrode layer, a second electrode layer, and an electrochromic material layer between the first electrode layer and the second electrode layer.

16. The display device according to claim 15, wherein the electrochromic material layer comprises N,N,N′,N′-tetraphenyl-1,4-phenylenediamine-tetraphenylphenylenediamine polymer, a chemical formula of the N,N,N′,N′-tetraphenyl-1,4-phenylenediamine-tetraphenylphenylenediamine polymer is:

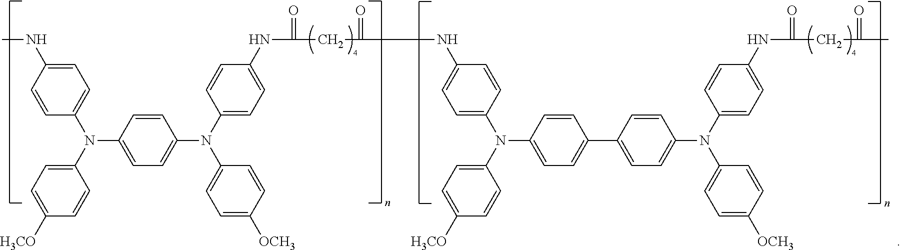

17. The display device according to claim 15, wherein each of the first electrochromic layer and the second electrochromic layer comprises a supporting electrolyte layer between the first electrode layer and the second electrode layer.

18. The display device according to claim 17, wherein the supporting electrolyte layer comprises viologen.

19. The display device according to claim 15, wherein first electrode layers of the first electrochromic layer or second electrode layers of the second electrochromic layer are connected to each other to form a continuous electrode layer.

20. The display device according to claim 15, wherein the light emitting layer comprises sub-light emitting layers corresponding to the sub-pixels of the display panel, the sub-light emitting layers comprise a red sub-light emitting layer, a green sub-light emitting layer, a blue sub-light emitting layer or a white sub-light emitting layer.
